(19) United States
(12) Patent Application Publication
(10) Pub. No.: US 2021/0044299 A1
(43) Pub. Date: Feb. 11, 2021

(54) METHOD AND APPARATUS FOR STOCHASTIC RING OSCILLATOR TIME-TO-DIGITAL CONVERTER WITH INTERLEAVED LOOP COUNTERS

(71) Applicant: Apple Inc., Cupertino, CA (US)

(72) Inventor: Stefan Tertinek, Linz (AT)

(21) Appl. No.: 16/977,627

(22) PCT Filed: Mar. 30, 2018
(86) PCT No.: PCT/US2018/025373

§ 371 Date: Sep. 2, 2020

(51) Int. Cl. H03L 7/099; H03L 7/091; H03L 7/191

(52) U.S. Cl. CPC H03L 7/0995; H03L 7/191; H03L 7/091

(57) ABSTRACT

A method and apparatus for generating a digital signal indicating a time between a start and a stop signal, including a short inverter ring operable to generate a clock signal. The clock signal is provided to a time-interleaved counter array that distributes the clock signal on a plurality of clock outputs as interleaved clock signals. Each interleaved clock signal is provided to a counter that counts a partial count value. The partial count values are combined to obtain a total count value as the digital signal indicating the time. A fine resolution signal is obtained from a chain of stochastic flip flops connected to outputs of the inverters in the short inverter ring. Multiple clock signal outputs of the inverter ring may be provided to multiple interleaved counters.

### TECHNICAL FIELD

The present disclosure relates generally to a method and apparatus for measuring time between two signals, and more particularly to a method and apparatus for time-to-digital conversion to determine a phase error between two signals.

### BACKGROUND

Determining a time difference between two signals is frequently performed in many circuits.

For example, radio frequency transceivers that are used in digital communications, such as in cellular telephone communications and in Wi-Fi (wireless-fidelity) communications, include digital phase-locked loop (DPLL) circuits which utilize time-to-digital converters (TDC) to measure a phase error between two clock signals.

Two types of digital phase-locked loop (DPLL) circuits using two different time-to-digital converters (TDC) are in use. A first type is a divider-based digital phase-locked loop circuit, for example, as used in cellular telephone communications. A second type is a divider-less digital phase-locked loop circuit such as used in Wi-Fi communications. The first type, or divider-based digital phase-locked loop circuit may use a third-order MASH (multi-stage noise shaping) sigma-delta modulator. It has the advantage that it may operate over longer measurement times for a radio frequency circuit, for example, over measurement times of 1 to 2 nanoseconds and may provide low fractional spurs such as by time-to-digital converter dithering. The time-to-digital converter (TDC) used in the divider-based DPLL is independent of the digitally controlled oscillator (DCO) frequency in a multi-band frequency application.

The time-to-digital converter of the divider-based DPLL is based on a ring oscillator and loop counter configuration.

### DESCRIPTION OF THE DRAWINGS

FIG. 1 is a functional block diagram of a ring oscillator time-to-digital converter using a loop counter;

FIG. 2 is a functional block diagram of a stochastic ring oscillator time-to-digital converter using interleaved loop counters;

FIG. 3 is a functional block diagram of an interleaved loop counter having two counters;

FIG. 4 is a functional block diagram of an interleaved loop counter having N counters;

FIG. 5 is a functional block diagraph of another aspect of the stochastic ring oscillator using interleaved loop counters;

FIG. 6 is a partial functional block diagram of another aspect of an inverter ring and stochastic flip flop assembly;

FIG. 7 is a signal timing diagram showing signals of the time-to-digital converter of FIG. 1 and showing signals of the time-to-digital converter of FIG. 3;

FIG. 8 is a circuit diagram of an implementation of a circuit wherein a clock signal is supplied to a single counter for counting as shown in FIG. 1 and the same clock signal is supplied to an interleaved counter for counting as shown in FIG. 3;

FIG. 9 is a signal timing diagram of the single counter portion of FIG. 8;

FIG. 10 is a signal timing diagram of the interleaved counter portion of FIG. 8 using two interleaved counters;

FIG. 11 is a flow chart of the method performed by the system; and

FIG. 12 is a functional block diagram of a system that may utilize the present method and apparatus.

### DETAILED DESCRIPTION

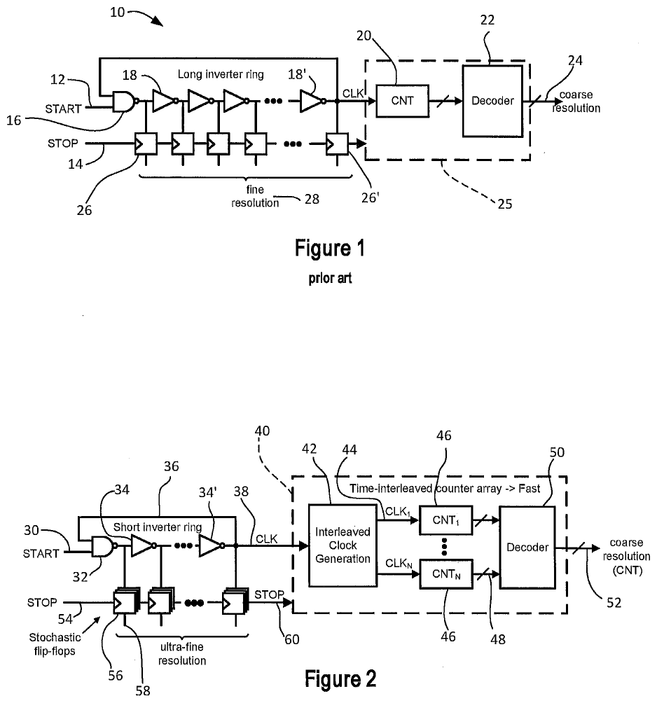

An example of a conventional ring oscillator and loop counter time-to-digital converter 10 is shown in FIG. 1.

In FIG. 1, two input signals are labeled a start signal 12 and a stop signal 14, which may be two clock signals or other signals for which a time difference or phase difference is to be determined. The start signal 12 is provided to a first input of a NAND gate 16, the output of which is provided to a series of inverters 18 in a long inverter ring. The output of the final inverter 18′ produces a signal after a time that is equal to the total time for the signal to be processed by each of the inverters in series in the long inverter ring. The output of the last inverter 18′ is fed back to the second input of the NAND gate 16 as a feedback signal. The feedback signal causes a change of state of the NAND gate 16 output, which is processed through the long inverter ring to provide a change of state at the output of the inverter ring. The changed output signal is fed back to the NAND gate 16, resulting in another signal being processed through the long inverter ring. As a result of the signals circulating in the long inverter ring, an alternating clock signal is generated at the output of the long inverter ring.

The output of the final inverter 18′ provides the alternating signal as a clock signal CLK to a counter 20. The long inverter ring must have a sufficient number of inverters connected in series to provide a delay between the consecutive clock pulses such that the counter may successfully count the output pulses. If the delay between clock pulses is short, the counter will not have completed counting the last pulse when the next pulse arrives. A longer delay between consecutive pulses provides time for the counter to complete the counting of the last pulse and settle in a state where it is ready to receive and count the next pulse. An example of a time-to-digital converter having a long inverter ring has 85 inverters. The high number of inverters in the inverter ring provides sufficient time between the state changes in the clock signal for the counter 20 to count the signals.

The counter 20 increments by one count each time it receives a pulse at its clock signal input from the inverter ring. The output of the counter 20 is provided to a decoder 22 that decodes the count signal to provide a coarse resolution output signal 24. The outputs of the counter 20 and the decoder 22 are shown as multiple lead outputs as indicated by the forward slash across the output leads. The counter 20 and decoder 22 together provide a counter array 25, as indicated by the broken line.

The second signal or stop signal 14 is provided to the clock input of a first flip flop 26 in a series of flip flops. Each subsequent flip flop 26 in the series receives the output of the prior flip flop 26 as a clock input. In certain implementations each flip flop 26 receives the same stop signal 14 as a clock input. The output of the NAND gate 16 is provided to an input of the first flip flop 26. Each inverter 18 in the inverter series has its output connected to an input of a corresponding flip flop 26. The output of the final flip flop 26′ is provided to the counter array 25 as a stop signal. The stop signal from the final flip flop 26′ may stop the counter 20 or may output the current count value and may reset the counter 20 to all zeros to prepare the counter array 25 for the next measurement.

The counter 20 increments for each pulse received from the final inverter 18′ and stops counting when the counter array 25 receives the stop signal from the final flip flop 26′. The decoder 22 reports the decoded counter output as a coarse resolution indication of the time difference between the start and stop signals 12 and 14. The flip flops 26 each include a state output that is read (as indicated by the bracket) as a fine resolution signal or information 28 of the time difference between the start and stop signals 12 and 14. The fine resolution information 28 breaks down the intervals reported by the coarse resolution information 24 into smaller increments for a higher resolution signal. In use, the coarse resolution information 24 and the fine resolution information 28 are considered together as the final output code for the time difference between the signals.

The second type of digital phase-locked loop (DPLL) is the divider-less DPLL. The divider-less DPLL utilizes first order sigma-delta modulation. This provides for short measuring times, for example, on the order of 250 picoseconds but has high fractional spurs, despite using TDC linearization. Depending on the application, the measuring time may be higher. The divider-less DPLL may use an ultra-high resolution stochastic flash time-to-digital converter, one example of which has a resolution of 0.6 picosecond, but the time-to-digital converter is configured for one oscillator frequency, for example the Wi-Fi high band frequency, and requires a high peak current. The high peak current, which may have a peak value of 40 mA, can cause a problem on the chip, in what is referred to as crosstalk.

The stochastic flash TDC (SF TDC) circuits use large numbers of flip flop elements. In some examples, 680 flip flop elements are undergoing simultaneous clocking, resulting in a 40 mA peak current. As each flip flop latches to an output value, it draws a latching current. The simultaneous latching of the large numbers of flip flops draws a high peak current from the power supply of the integrated circuit chip on which the circuit is provided. The high peak current triggers spurious effects in other components on the chip. The large numbers of flip flops latching at the same time results in crosstalk, or coupling, between the TDC and other components on the chip.

The two types of time-to-digital converters used in DPLL circuits provide either long measurement times but without ultra-high resolution, or provide short measurement times but with high peak currents as a result of simultaneous clocking of large numbers of flip flops. It would be desirable to provide a unified DPLL circuit that supports both divider-less and divider-based operation and that provides long measurement times with ultra-high resolution and low peak currents.

The present method and apparatus provides a time-to-digital converter that includes interleaved loop counters. A short inverter ring may be used in the time-to-digital converter, reducing the number of flip flops required and providing high resolution while permitting long measurement times. The shorter inverter ring may reduce the number of flip flops that latch at the same time, reducing the peak current, thereby reducing coupling and crosstalk of the time-to-digital converter with other circuits.

In FIG. 2, a start signal 30 or first clock signal is provided to a NAND gate 32, the output of which is provided to a first inverter 34 of a series of inverters that each provide an output signal into an input of the next inverter 34 in the series. The inverters 34 are connected in a short inverter ring. The short inverter ring has fewer inverters connected in series than the known long inverter rings, as shown for example in FIG. 1, and in certain embodiments has a significant reduction in the number of inverters used. In an example, 84 flip flop elements are used, where 680 had been used a comparable prior art time-to-digital converter. A result of providing fewer inverters 34 in series is that it takes less time for a signal to move through the inverter ring.

A final inverter 34′ in the inverter ring generates an output signal that is fed back to the NAND gate 32 as a feedback loop 36. The signal from the feedback loop 36 triggers another signal change to move through the inverter ring. As a result of fewer inverters 34 in the inverter ring, the signal change at the final inverter 34′ occurs more frequently, at a higher clock frequency, than for an inverter chain formed of more inverters. The time between state changes in the clock signal changes is too short for most counters to successfully count the signal. The higher clock frequency results in a higher resolution for the time counted by the clock signals.

The output of the final inverter 34′ is a clock signal CLK on lead 38 that is input to a time-interleaved counter array 40. The time-interleaved counter array 40 is capable of successfully counting the rapid clock signals received on the lead 38 from the short inverter ring. The counter array 40 includes an interleaved clock generator 42. The interleaved clock generator 42 is configured to perform a time interleave function so that the rapid clock signals are distributed to a plurality of counters. The interleaved clock generator 42 breaks the rapid clock signals on the lead 38 down onto multiple clock signals CLK₁-CLK_{N} on separate clock signal outputs 44. For N clock signal outputs 44, each output 44 receives a clock signal for each 1/N clock signals received on the lead 38. Each next output 44 receives the next clock signal. The interleaved clock generator deals out the clock signals to each next output 44 much like a card dealer deals out cards to each next player.

The interleaved clock generator 42 produces a plurality clock signals on a plurality of clock signal outputs 44, shown as the clock signal CLK₁ to clock signal CLK_{N}. The clock signal outputs 44 are each connected to an input of a respective counter 46, shown here as a plurality of counters CNT₁ to CNT_{N}. Each counter 46 operates to count the clock signals that it receives. Each of the counters 46 receive one out of every N clock signals from the output 38 of the shorter inverter ring. Because the interleaved clock generator 42 distributes the clock signals to N counters 46, each clock signal from the output 38 gets counted by one of the N counters. The short inverter ring may produce clock signals too rapidly for the signals to be accurately counted by a single counter. Distributing the clock signals to a plurality of counters 46 enables the counters to count the clock signals.

For instance, a counter circuit that receives a signal to be counted must complete the transition from the state prior to receiving the signal to a new state at which the newly received signal has been counted. The counter circuit requires time to make the transition and settle into its new state. Once the counter has completed the transition and is in its new state it can be said to have relaxed. If a next signal reaches the input after the counter circuit has completed the transition and the circuit has relaxed, the next signal will be counted successfully. However, if the next signal reaches the input while the counter is still in transition between states, before it has relaxed, an error will occur.

By distributing or dividing the clock signals among a plurality of counters 46 so that each counter 46 receives one out of every N clock signal, the counters 46 have time between the received signals to complete the transition from one state to the next state and reach a relaxed state. Time is provided between consecutive clock signals on the leads 44 for the counters 46 to reach a settled state, or relaxed state, after transitioning to a new count value. The counters 46 count each signal they receive without an error by the counting circuits. A rapid clock signal on lead 38 may be successfully counted.

The counters 46 each accumulate a count value that is 1/Nth of the pulses on the clock signal lead 38. The counters 46 each provide a partial count value. The partial count values of each counter 46 are output on multiple parallel leads 48 that are connected from each counter 46 and that are connected to inputs of a decoder 50. The parallel outputs 48 from each counter 46 carry digital code signals to provide a parallel output of the partial count value by the counter 46.

The drawing uses a forward slash symbol across a single output lead from each counter 46 to indicate that each counter 46 has multiple parallel output leads for outputting the count value. The forward slash symbol is used elsewhere in the drawings to indicate that multiple parallel leads are provided where a single lead with a slash symbol is shown.

The decoder 50 receives the parallel input partial count values provided by each of the counters 46 and combines the partial count values into a total count value that is output on an output lead 52. The total count value on lead 52 is the result of adding the partial count values on leads 48 from each of the counters 46 to one another. The output lead 52 includes a plurality of parallel leads as indicated by the forward slash. The total count value on lead 52 is a coarse resolution count value for the time-to-digital converter. However, since the clock signal provides a more rapid clock pulse, the coarse resolution count value has a higher resolution due to the short inverter chain than for converters that use a long inverter chain.

The second clock signal, or stop signal, is provided on lead 54 to a series of stochastic flip flops 56. After the start or first clock signal is received and before the stop or second clock signal is received, the stochastic flip flops 56 record the state of the inverters 34 in the inverter ring. The first stochastic flip flop 56 receives the output signal from the NAND gate 32 and records its value. The second stochastic flip flop 56 in the series receives the output signal from the first inverter 34 and records its value. Each subsequent stochastic flip flop 56 receives the output signal from each subsequent inverter 34. The stochastic flip flops 56 store the values that are moving through the inverter ring as they move from inverter to inverter 34. When the stop signal or second clock signal is received on the lead 54, the states of the stochastic flip flops 56 are read out. The output value of each stochastic flip flop 56 is provided at outputs 58. The outputs 58 provide an ultra-fine resolution time signal, which further divides the time signal at the coarse output 52 into smaller increments. The ultra-fine resolution signal is added to the coarse resolution value to obtain a high definition time signal of the difference between the start and stop signals.

The stop signal or second clock signal is provided as a stop signal to the time-interleaved counter 40 at lead 60. The stop signal on lead 60 causes the count value on the coarse resolution output 52 to be output as the coarse count value of the time difference between the start and stop signals.

The stop signal to the stochastic flip flops 56 and to the time-interleaved counter array 40 may cause the circuits to stop operating temporarily, or the circuits may continue operating and the stop signal may cause the current state of the circuits to be read out.

The flip flops 56 could each be a single flip flop, which would keep the number of flip flop elements in the time-to-digital converter very low and would reduce the peak load current significantly. If a single flip flop is used, stochastic variations as between the flip flops may lead to inaccuracies in the read out value. An improvement in accuracy may be achieved by replacing each of the flip flops 56 with a stochastic flip flop. As is known, a stochastic flip flop 56 includes a plurality of flip flop elements connected to each receive the same input at the same time. The all of the flip flop elements of the stochastic flip flop process the signal at the same time and generate outputs. Because of differences (stochastic variability) between the flip flop elements of the stochastic flip flop, some flip flop elements generate an output sooner and some generate an output later. The outputs of the flip flop elements in the stochastic flip flop are collected and a determination is made from the collected outputs as to what is the state of a majority of the flip flops. The output value of the majority of elements is taken to be the output value of the stochastic flip flop 56. Stochastic flip flops reduce or eliminate stochastic variations in the output that are the result in differences in signal processing speed that may occur in individual flip flop elements. By taking the output as a vote of the majority, the accuracy of the flip flop outputs 58 is increased. In certain examples, eight flip flop elements may be provided in each of the stochastic flip flops.

In further detail, a stochastic flip flop may include a bunch of regular flip flops. Due to process variations in a regular flip flop, the voltage threshold at which the clock input latches the data (D) through to the output (Q) is random. For example, the threshold may be Gaussian distributed (e.g. for a supply voltage of VDD=1 V, the threshold may be Gaussian distributed around an expected value of VDD/2=0.5 V). Stochastic flip flops are obtained by having multiple regular flip flops connected in parallel to the same clock signal and to the same data input. If the clock signal is close to a 0->1 transition of the data signal, then, due to this random variation of the threshold, some flip flops will latch a 0 through to the output, while some will produce a 1 (if all FFs had the same threshold, all output would be either 0 or 1). If the random voltage thresholds are considered as random switching points in time, then stochastic flip flops are a way to increase the resolution of a TDC by making use of the random process variation.

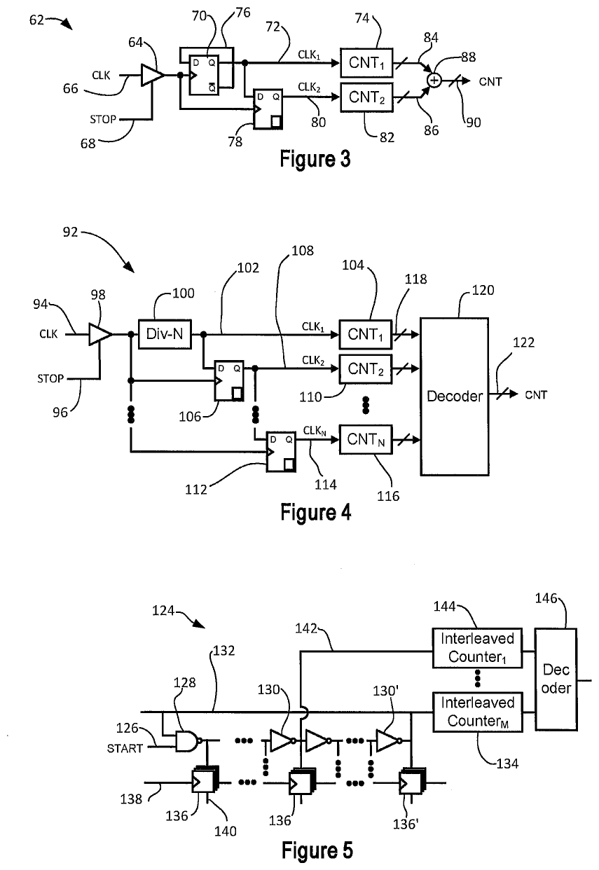

Turning to FIG. 3, an example of an interleaved counter 62 is shown. The interleaved counter 62 includes a buffer 64 having a clock signal input 66 and a stop signal input 68. The output of the buffer 64 is provided to a clock input of a D flip flop 70. The Q output of the D flip flop 70 provides a first clock signal CLK₁ on lead 72 to a first counter CNT₁, reference number 74. The inverting output Q̅ is connected in a feedback loop 76 back to the D input. The flip flop 70 generates a rising signal output for every two clock input signals. The flip flop 70 operates as a divide by 2 circuit. A second flip flop 78 has its clock input connected to the output of the buffer 64 and its D input connected to the Q output of the flip flop 70. The second flip flop 78 generates a second clock signal CLK₂ on lead 80 at every second clock signal input. The second clock signals on the lead 80 are generated by clock signals that do not generate a clock signal on the CLK₁ lead 72. The output of the second flip flop 78 is provided to a second counter 82.

The first counter 84 provides a count value on parallel output leads 84 and the second counter provides its count value on parallel output lead 86, both of which are connected to an adder 88 that adds the two count values together and produces a combined count value CNT on lead 90.

In FIG. 3 is an example of an interleaved counter that divides the counting function by two. A generic interleaved counter 92 is shown in FIG. 4, in which the counting function is divided by N, where N is greater than one. A clock signal on lead 94 and a stop signal on lead 96 is connected to a buffer 98. The output of the buffer 98 is connected to a divide by N circuit 100, where N is the number of counters provided. The output of the divide by N circuit 100 provides every Nth signal on lead 102 to the first counter 104. The output of the divide by N circuit 100 is provided to a D input of a flip flop 106, the input of which receives the clock signal from the buffer 98. The output of the divide by N circuit triggers the flip flop 106 to operate and produce a signal at its Q output when the second clock signal arrives. The output of the second flip flop 106 is provided over lead 108 to a second counter 110.

The output of the buffer 98 is provided to a clock input of an Nth flip flop 112. The D input of the Nth flip flop 112 is connected to the output of the (N−1)th flip flop. In the example, if N equals 3, the (N−1)th flip flop would be the flip flop 106. For N greater than 3, the (N−1)th flip flop is represented by the ellipses. The Nth flip flop 112 generates an output on lead 114 at the next clock signal CLK_{N} from the buffer following the output by the (N−1)th flip flop. The clock signal CLK_{N} on lead 114 is provided to a counter 116.

The ellipses in FIG. 4 indicate that additional outputs from the buffer 98 may be connected to additional flip flops, that the D input of each flip flop is connected to the Q output of the preceding flip flop, and that the output of each flip flop is connected to a respective counter. Any number of flip flops and counters may be selected as desired to divide the input clock signal into N interleaved clock signals, each counted by its own counter. The figures illustrate N=2 and N=3. Systems using N=4, 5, 6, 7, 8, 9, 10, or more are envisioned.

The outputs of the counters 104, 110 and 116 are provided on parallel output leads 118 to a decoder 120. The decoder 120 receives the partial counts from the counters 104, 110 and 116 and operates to combine the partial counts into a total count that is output on lead 122. The total count value may be a coarse value. The lead 122 includes a plurality of parallel output leads as indicated by the forward slash.

FIG. 5 shows a time-to-digital converter 124 that utilizes multiple interleaved counters. In particular, a start signal or first clock signal is received on lead 126 and provided to an input of a NAND gate 128. The output of the NAND gate 128 is input to a first inverter 130 of an inverter ring. The clock signals pass from inverter 130 to inverter 130 until a last inverter 130′ is reached. The output of the last inverter 130′ of the inverter ring is fed back in a feedback loop 132 to the second input of the NAND gate 128 as well as to an input of an interleaved counter_{M} 134.

The output of each inverter 130 and of the NAND gate 128 is provided to an input of respective stochastic flip flops 136. The stochastic flip flops 136 are connected to each receive the stop signal or second clock signal that is input on stop lead 138. The output of the last stochastic flip flop 136′ stops the counter or at least causes the count value of the counter to be read out. The stochastic flip flops 136 have outputs 140 that may provide the fine count value.

So far, the time-to-digital converter 124 is similar to the time-to-digital converters described above. In the illustrated TDC 124, however, an intermediate output 142 is collected from an inverter 130 in the inverter ring. The intermediate output 142 is provided to an interleaved counter₁ 144. The interleaved counter 144 collects count values just as the interleaved counter 134 but without a time delay. In particular, each interleaved counter 134 and 144 increments the count value each time the signal passes in the inverter ring, i.e. once each lap of the inverter ring. The counter 144 will increment the count value when the first inverter 130 outputs a signal. The counter 134 increments the count value later, after the intervening inverters 130 and the final inverter 130′ have output a signal. Any difference between the count values of the counters 134 and 144 will indicate an incremental time, or fine count value, that provides a value between the coarse count values. By using one intermediate output as in FIG. 5, an increment of the coarse output is divided into two finer divisions. Further increments are possible. The outputs of the interleaved counters 134 and 144 are provided to a decoder 146 for decoding. The decoder 146 may provide both the coarse and fine resolution counts, for example, as explained below.

By providing a plurality of intermediate outputs from a plurality of the inverters and by counting the intermediate outputs in a plurality of interleaved counters, the fine resolution count value may be determined by comparing the interleaved counter output values to one another. By way of illustration and without limiting the invention, if eight intermediate outputs are provided to eight interleaved counters, then a fine resolution value of ⅛th the duration of the coarse resolution output is provided. For example, if the first two counters are one increment higher than the next six counters, then the signal has progressed ¼th of the way through the inverter ring before the stop signal is received. The time between the signals is the last counter value plus ¼^{th} of the coarse count interval. If three counters are at a higher increment, then the fine count is ⅜ths of the coarse count interval, and so on. Other numbers of intermediate outputs, and other interleaved counters may be provided to provide other fine resolution timing signals.

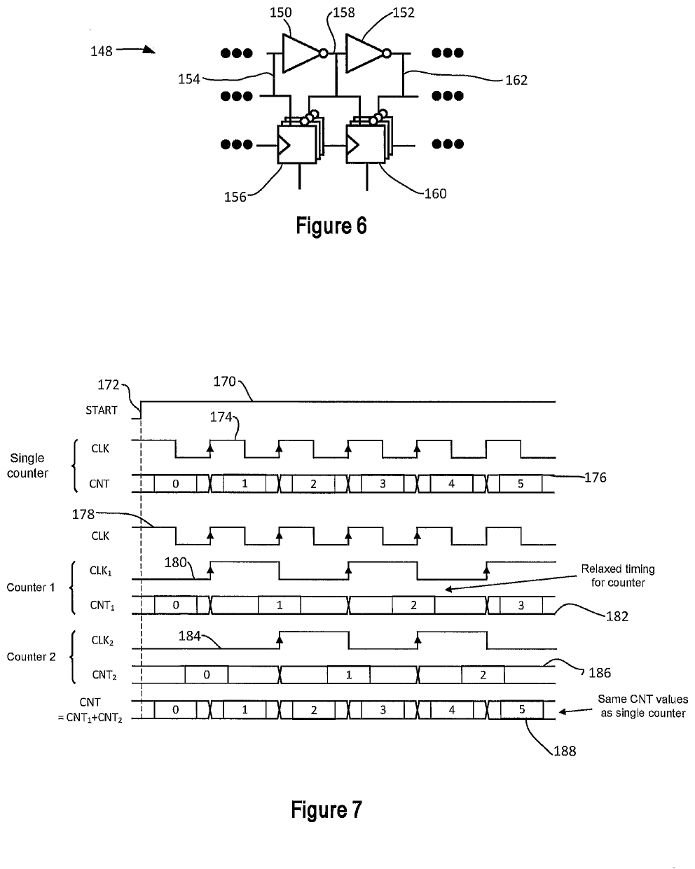

In FIG. 6, a portion of an inverter ring 148 is shown. The inverter ring 148 may be used in place of the inverter rings described above. An inverter 150 receives an input signal on lead 154. The output of the inverter 150 is provided to the next inverter 152 in the inverter ring. The input signal 154 is also provided to an input of a stochastic flip flop 156. When the inverter 150 generates an output signal on lead 158, the output signal is not only provided to the next inverter 152 but is also provided to NOT inputs of the stochastic flip flop 156. The signal in the stochastic flip flop 156 as a result of receiving the input on the lead 154 is removed by the signal on the lead 158.

The signal on the lead 158 is provided to the input of the stochastic flip flop 160 so that the signal is stored on the stochastic flip flop 160. The output of the inverter 152 is provided to NOT inputs of the stochastic flip flop 160 to remove the signal once the inverter 152 has generated its output. By storing the signal and then clearing the signal in each consecutive stochastic flip flop, the fine resolution signal indicates which inverter in the inverter ring is processing the signal when the stop signal arrives. The fine resolution signal is provided as a signal from a single stochastic flip flop in the series. The fine resolution signal for an inverter ring of FIG. 2 having eight inverters may read out as 1-1-1-1-1-0-0-0, for example. The fine resolution signal for an inverter ring of FIG. 6 may read out as 0-0-0-0-1-0-0-0 for the same result. This result may be easier to detect and/or easier to convert to a fine resolution output value.

FIG. 7 is a signal diagram that shows that a two counter interleaved counter can be operated to produce the same count output as a single counter circuit. The example shows signals of a time-to-digital converter using a short inverter loop but having a single counter and signals of the time-to-digital converter of FIG. 2 having two interleaved counters. A start signal 170 has a rising signal edge 172 that starts the counting by the time-to-digital converter. The short inverter ring produces a clock signal 174 at a high frequency that includes a series of pulses. The rising edges are sensed for counting. A count signal 176 counts each rising edge of the clock signal. The count value that is reached when the stop signal is reached is a digital indication of the time difference between the start signal and the stop signal. The intervals between the rising edges of the clock signal are relatively short as a result of the short inverter ring used. As a result the clock signal 174 may be at a frequency that is close to the highest possible count frequency of any counter in a given process technology.

Due to process variations in the implementation of a counter circuit, the frequency of clock signal 174 may be too high for some counters to successfully count the clock signal.

Clock signal 178 is also provided by the short inverter ring of FIG. 2 and is essentially the same signal as clock signal 174. The interleaved clock generator produces a first clock signal 180 that has a rising signal only one of every two rising signals of the clock signal. The first clock signal 180 is provided to the first counter to produce a first partial count value 182. The first clock signal 180 inputs rising level signals to the first counter at intervals permitting the counter circuit to reach a relaxed state after incrementing a count value. As a result the first clock signal 180 will be counted successfully.

The interleaved counter provides a second clock signal 184 that includes a rising value every second rising value of the clock signal, or on the second of every two rising values of the clock signal. The second clock signal 184 is counted by the second counter to provide a count value 186. The count values 182 and 186 are added together to produce a total count value 188. The total count values are the same values as in the prior art, but the clock signal will be counted successfully by the interleaved counter even if the counter circuit is subject to process variations in the implementation.

Another factor that can impact the ability of the time-to-digital converter is process variations in the circuit. For example, an inverter ring may be configured to generate a clock frequency of 10 GHz. The clock signal may be input to a counter that is capable of counting at a maximum frequency of 10 GHz. Process variations may cause some samples of the inverter ring to generate a clock frequency at 11 GHz. The single counter will fail. Use of an interleaved counter will provide a count even where process variations in the circuit might cause operation above a maximum frequency of a counter. Specifically, two interleaved clock signals are generated from the original clock signal, each having the frequency of the original clock signal. The interleaved clock signals are each counted by identical versions of the counter. The outputs of the two counters are added together to obtain a final count value. If the inverter ring happens to run at 11 GHz, then the two counters will receive clock signals at 5.5 GHz, which is a frequency the counters can count without failing. Using two counters capable of counting clock signals up to 10 GHz means that the inverter ring could generate a clock signal up to 20 GHz and yet the counters would count the signal even with only two interleaved counters. Other numbers of interleaved counters and other clock frequencies are of course possible.

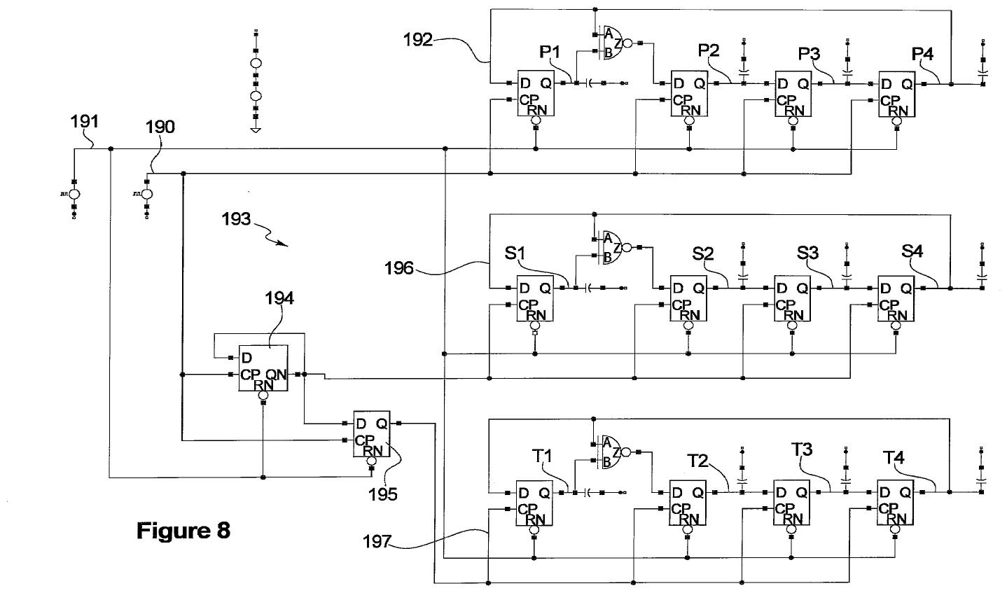

FIG. 8 shows two circuits that compares a single counter to an interleaved counter using two counters. A clock signal to be counted is provided at 190. Counting is to continue until a stop or reset signal 191 is provided, after which the clock may start again. The clock signal 190 and stop or reset signal 191 are provided to a single counter 192 shown at the top portion of the figure that includes four flip flops that operate to generate count pulses P1, P2, P3, and P4. By comparison, the lower portion of the figure shows an example of an interleaved counter 193 similar to the counter of FIG. 3 where N=2. The illustrated interleaved counter 193 includes a divide by 2 circuit having flip flops 194 and 195 connected to receive the clock signal 190. The flip flop 194 provides the first interleaved clock to the first counter 196. The first counter is configured like the single counter 192 and operates to generate the count signals S1, 52, 53 and 54. The second flip flop 195 of the divide by 2 circuit provides a second interleaved clock signal to a second counter 197. The second counter 197 is configured like the first counter 196 and includes four flip flops producing count signals T1, T2, T3 and T4. The figure is an implementation of the circuits of FIGS. 1 and 3. In the illustration, the single counter 192 is a single four-bit LFSR counter with a capacitive load. The interleaved counter uses two 4-bit LFSR counters 196 and 197 with a capacitive load.

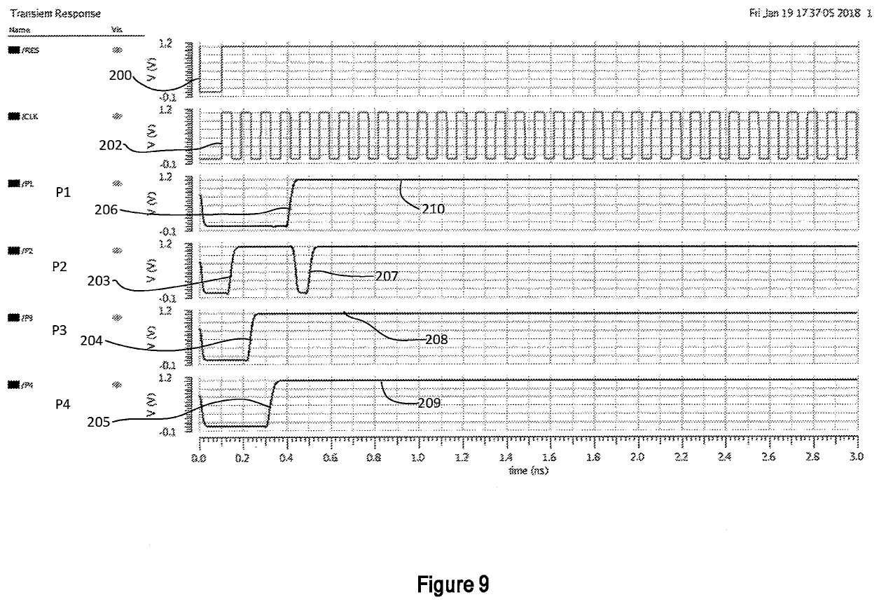

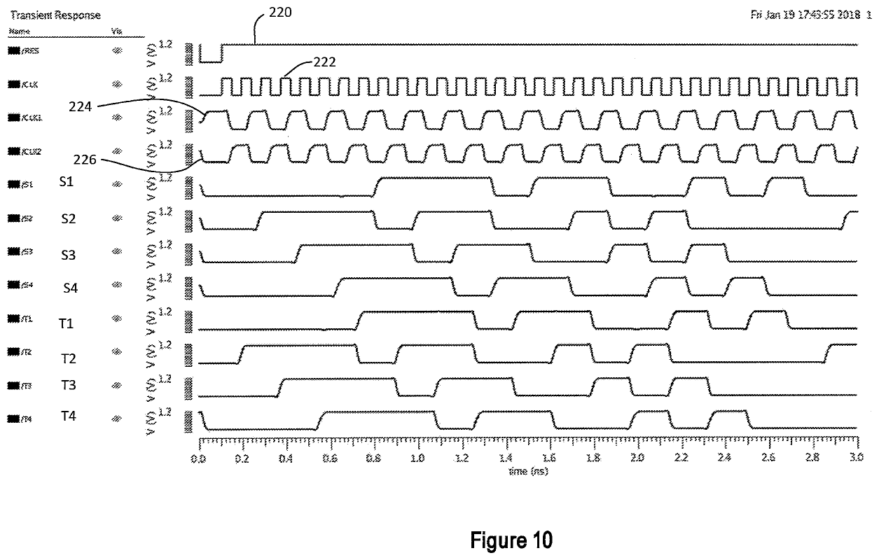

FIGS. 9 and 10 show simulation results for the circuits of FIG. 8. FIG. 9 shows the operation of the single count circuit at the top portion of FIG. 8. In the signal diagram a reset signal 200 triggers the running of a clock signal 202. The clock signal 202 runs at a high frequency as a result of the short inverter ring. In the example, the clock signal 202 is operating at 11.2 GHz. The clock signal 202 is input to a single LFSR counter. The single counter has a maximum input frequency of 10 GHz, for example. The signals that appear at the flip flop outputs P1, P2, P3 and P4 are shown. At 203, the first positive going pulse of the clock signal 202 is counted. At 204, the second positive going pulse is counted, at 205 the third pulse is counted, at 206 the fourth pulse is counted, and at 207 fifth pulse is counted, but as shown at 208, 209 and 210, the counterfails to count the further pulses due to a timing violation in the critical path.

In FIG. 10, the signals of the interleaved counter array in the lower portion of FIG. 8 are shown. The resulting interleaved clock signals that are at a low enough frequency that each counter achieves a relaxed state before a next signal is provided to its input. The start signal 220 initiates the high frequency clock signal 222, which is broken down into a first clock signal 224 and a second clock signal 226 by an interleaved clock generator. The first and second clock signals are provided to respective ones of the two counters, which generate the count signals S1, S2, S3, and S4 in the first counter and the signals T1, T2, T3 and T4 in the second counter. The first and second counters are of the same construction as the single counter that produces P1, P2, P3 and P4, and the same clock signal is provided to the single counter and the interleaved counter, but the interleaved counters operate to count the pulses without failing due to a timing violation. The number of inverters required to perform the time-to-digital conversion has been reduced by providing a short inverter ring in place of a long inverter ring. The result is lower peak current demands on the power supply as fewer flip flops are latching at the same time. For example, a reduction from 680 flip flops in the prior art to 84 flip flops in certain embodiments is achieved. The lower peak current demand ensures that the current supply is strong when the flip flops are latching. This may result in better latching. Lower peak current demands reduces the cross talk to other circuits that share the power supply, such as other circuits on the chip. Reduced coupling effects are provided as a result of fewer spurious components in the power supply. Fewer flip flops also means a smaller footprint on the chip for the time-to-digital converter.

The faster clock signal provides higher resolution for the time indication output by the time-to-digital converter.

The long inverter ring of as described herein may generate a clock signal at frequency that is low enough to be counted by a single counter. For example, the clock frequency provided by the long inverter ring may be counted by a fast single counter built using in a given process technology. By comparison, a short inverter ring such as may be used in the present time-to-digital converter may be capable of generating a clock signal at a frequency that is at too high to be counted by a single counter. An interleaved counter is provided to count the high frequency clock signal. The short inverter ring reduces the number of flip flops in the circuit. The short inverter ring may reduce the number of stochastic flip flops used. The additional flip flops required to provide the interleaved counter is nowhere near the number of flip flops required for a long inverter ring necessary for a single counter circuit. A net savings in flip flops is achieved.

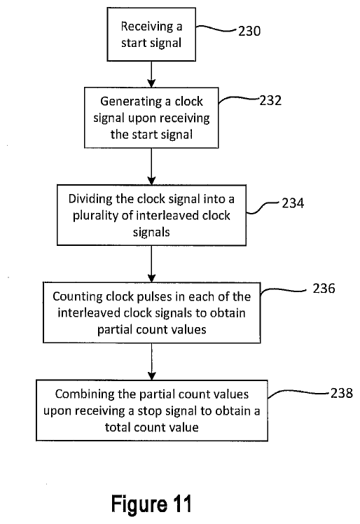

In FIG. 11, a first step 230 of receiving a start signal is followed by a step 232 of generating a clock signal. At 234 is provided dividing the clock signal into a plurality of interleaved clock signals. At 236, counting the clock pulses in each of the interleaved clock signals obtains partial count values. At 238 is provided the step of combining the partial count values upon receiving a stop signal to obtain a total count value.

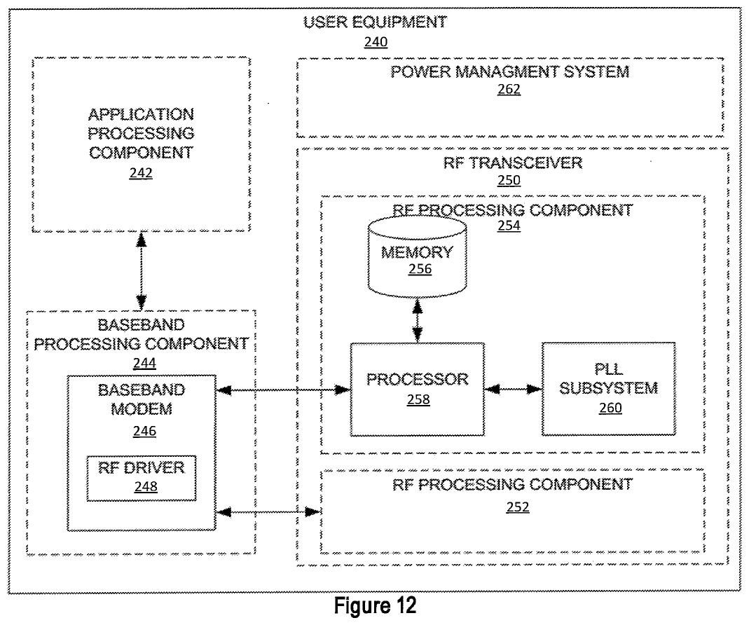

FIG. 12 shows a system diagram including user equipment 240 that includes an application processing component 242 communicating with a baseband processing component 244. The baseband processing component has a baseband modem 246 within which is an RF driver 248. The baseband modem 246 communicates with an RF transmitter 250. The RF transceiver has a first RF processing component 252 such as for transmitting, and a second RF processing component 254 such as for receiving. The second RF processing component 254 has a memory 256, a processor 258 and a phase-locked loop (PLL) subsystem 260. The PLL subsystem may include the present time-to-digital converter. A power management system 262 is also provided in the user equipment 240. The user equipment 240 may be a smart phone, tablet or other device.

Various aspects of the method and apparatus are provided according to the following.

In a first aspect, a time-to-digital converter, comprising: an inverter ring configured to generate a clock signal at a clock signal output upon receiving a start signal at a first input; a flip flop chain including an second input to receive a stop signal and having a stop signal output; and a time interleaved counter array connected to receive the clock signal from the inverter ring and to receive the stop signal from the flip flop chain, the time interleaved counter array including: a plurality of counters connected to receive a plurality of interleaved clock signals from the inverter ring and generate partial count signals as counts of the interleaved clock signal received by the corresponding counter; and a decoder connected to receive the partial count signals and configured to combine the partial count signals into a total count value.

In a second aspect, a time-to-digital converter according to a first aspect, wherein the inverter ring includes a feedback loop connecting the clock signal output to an input of the inverter ring, the inverter ring being a short inverter ring that is operable to generate a clock pulse having a clock period less than a settling time of at least one of the plurality of counters.

In a third aspect, a time-to-digital converter according to a first aspect, wherein the inverter ring includes a plurality of inverters connected in series.

In a fourth aspect, a time-to-digital converter, comprising: an inverter ring including a plurality of inverters connected in series, the inverter ring having a logic gate with a first input to receive a start signal, the logic gate having an output connected to a first inverter in the inverter ring, the inverter ring having a clock signal output, a feedback loop connected from the clock signal output of the inverter ring to a second input of the logic gate, the inverter ring being operable to generate a clock signal at the clock signal output upon receiving the start signal at the first input of the logic gate; a flip flop chain including a plurality of flip flops connected in series, the flip flop chain including a second input to receive a stop signal, the flip flop chain including flip flops connected to receive outputs of corresponding inverters in the inverter ring, the flip flop chain having a stop signal output, the flip flop chain being operable to output a stop signal; and a time interleaved counter array connected to receive the clock signal from the inverter ring and to receive the stop signal from the flip flop chain, the time interleaved counter array including: a plurality of counters connected to receive a plurality of interleaved clock signals from the inverter ring, each of the plurality of counters being operable to generate a partial count signal as a count of the interleaved clock signal received by the corresponding counter; and a decoder connected to receive the partial count signals, the decoder being operable to combine the partial count signals into a total count value, the total count value corresponding to a digital value of a time between the start signal and the stop signal.

In a fifth aspect, a time-to-digital converter according to a fourth aspect, wherein the time interleaved counter array includes: an interleaved clock generator connected to receive the clock signal from the inverter ring and being operable to distribute the clock signal to a plurality of clock outputs as interleaved clock signals; and wherein the plurality of counters are connected to respective ones of the plurality of clock outputs to each receive a corresponding interleaved clock signal.

In a sixth aspect, a time-to-digital converter according to a fifth aspect, wherein the interleaved clock generator distributes the clock signal on a first number of clock outputs, the interleaved clock generator including a divide by first number element connected to receive the clock signal from the inverter ring.

In a seventh aspect, a time-to-digital converter according to a fifth aspect, wherein the interleaved clock generator is operable to output a first clock pulse on a first clock output of the plurality of clock outputs and configured to output a second clock pulse on a second clock output of the plurality of clock outputs.

In an eighth aspect, a time-to-digital converter according to a fourth aspect, wherein the inverter ring includes a plurality of outputs at which are generated time interleaved clock signals; and wherein the plurality of counters are connected to respective ones of the plurality of outputs of the inverter ring.

In a ninth aspect, a time-to-digital converter according to an eighth aspect, wherein the plurality of outputs of the inverter ring are connected from outputs of a plurality of the inverters in the inverter ring.

In a tenth aspect, a time-to-digital converter according to a ninth aspect, wherein the plurality of counters connected to the plurality of outputs of the inverter ring include a plurality of interleaved counters.

In an eleventh aspect, a time-to-digital converter according to a tenth aspect, wherein each of the interleaved counters includes: an interleaved clock generator connected to receive the clock signal from the inverter ring and being operable to distribute the clock signal to a plurality of clock outputs as interleaved clock signals; and the plurality of counters are connected to respective ones of the plurality of clock outputs to each receive a corresponding interleaved clock signal.

In a twelfth aspect, a time-to-digital converter according to a fourth aspect, wherein the flip flop chain includes a chain of stochastic flip flops connected in series, each of the stochastic flip flops including a plurality of flip flops, each stochastic flip flop being operable to generate an output corresponding to an output value of a majority of the flip flops of the stochastic flip flop.

In a thirteenth aspect, a time-to-digital converter according to a fourth aspect, wherein each flip flop in the flip flop chain includes a first input connected to an input of the corresponding inverter in the inverter ring, each flip flop in the flip flop chain including a second input connected to an output of the corresponding inverter in the inverter ring.

In a fourteenth aspect, a time-to-digital converter according to a twelfth aspect, wherein one of the first and second inputs of each flip flop in the flip flop chain is an inverted input.

In a fifteenth aspect, a time-to-digital converter according to a fourth aspect, wherein the inverter ring is a short inverter ring.

In a sixteenth aspect, a time-to-digital converter according to a fifteenth aspect, wherein the inverter ring generates a series of clock pulses having a time between subsequent clock pulses less than a relaxation time of the counters, and wherein the interleaved clock signals have a time between subsequent clock pulses greater than a relaxation time of the counters.

In a seventeenth aspect, a method for determining a time between a start signal and a stop signal, comprising: generating a clock signal upon receiving the start signal; dividing the clock signal into a plurality of interleaved clock signals; counting pulses of each of the interleaved clock signals to accumulate a plurality of partial count values; combining the plurality of partial count values with one another to obtain a total count value upon receiving the stop signal, the total count value corresponding to a digital indication of a time between the start signal and the stop signal.

In an eighteenth aspect, a method according to a seventeenth aspect, wherein the generating the clock signal includes generating the clock signal using a short inverter ring.

In a nineteenth aspect, a method according to a seventeenth aspect, wherein the clock signal generated in the generating step has a time between subsequent clock pulses less than a relaxation time of the counters; and wherein the interleaved clock signal obtained in the dividing step have a time between subsequent clock pulses greater than a relaxation time of the counters.

In a twentieth aspect, a method according to a seventeenth aspect, wherein the total count value is a coarse resolution count value; wherein the generating the clock signal includes communicating the start signal through a series of logic elements connected in a ring; and further comprising: receiving the outputs of the logic elements in the ring by a series of stochastic logic elements; and obtaining a fine resolution count value at outputs of the stochastic logic elements.

In a twenty-first aspect, a method according to a seventeenth aspect, wherein the series of logic elements connected in a ring are inverters connected in an inverter ring.

In a twenty-second aspect, a method according to a seventeenth aspect, wherein the receiving the outputs of the logic elements by the stochastic logic elements includes receiving an output of a logic element in the series at an inverting input of a stochastic logic element and receiving the same output of the logic element in the series at a non-inverting input of a next subsequent stochastic logic element in the series.

In a twenty-third aspect, a method according to a seventeenth aspect, wherein the generating the clock signal includes generating a plurality of clock signals; and wherein the dividing the clock signal includes dividing each of the plurality of clock signals into interleaved clock signals.

In a twenty-fourth aspect, a time-to-digital converter, comprising: a short inverter ring including a plurality of inverters connected in series, the short inverter ring having a logic gate with a first input to receive a start signal, the logic gate having an output connected to a first inverter in the short inverter ring, the short inverter ring having a clock signal output, a feedback loop connected from the clock signal output of the short inverter ring to a second input of the logic gate, the short inverter ring being operable to generate a clock signal at the clock signal output upon receiving the start signal at the first input of the logic gate; a flip flop chain including a plurality of stochastic flip flops connected in series, the flip flop chain including a second input to receive a stop signal, the flip flop chain including stochastic flip flops connected to receive outputs of corresponding inverters in the inverter ring, the flip flop chain having a stop signal output, the flip flop chain being operable to output a stop signal; and a time interleaved counter array connected to receive the clock signal from the inverter ring and to receive the stop signal from the flip flop chain, the time interleaved counter array including: an interleaved clock generator connected to receive the clock signal from the inverter ring and being operable to distribute the clock signal to a plurality of clock outputs as a plurality of interleaved clock signals, the interleaved clock generator is operable to output a first clock pulse on a first clock output of the plurality of clock outputs and is operable to output a second clock pulse on a second clock output of the plurality of clock outputs; a plurality of counters connected to respective ones of the plurality of clock outputs to each receive a corresponding interleaved clock signal, each of the plurality of counters being operable to generate a partial count signal as a count of the interleaved clock signal received by the corresponding counter; and a decoder connected to receive the partial count signals, the decoder being operable to combine the partial count signals into a total count value, the total count value corresponding to digital value of a time between the start signal and the stop signal, wherein the short inverter ring generates a series of clock pulses having a time between subsequent clock pulses less than a relaxation time of the counters, and wherein the interleaved clock signals have a time between subsequent clock pulses greater than a relaxation time of the counters.

In a twenty-fifth aspect, a time-to-digital converter, comprising: means for generating a clock signal upon receiving a start signal; means for generating a plurality of interleaved clock signals on a plurality of output puts from the clock signal; means for counting the interleaved clock signals to obtain partial count values; and means for combining the partial count values to obtain a total count value, the total count value being obtained upon receipt of a stop signal, the total count value being a digital value corresponding to a time between the start signal and the stop signal.

In a twenty-sixth aspect, a time-to-digital converter according to a twenty-fifth aspect, wherein the means for generating a clock signal generates a plurality of clock signals; and wherein the means for generating a plurality of interleaved clock signals generates a plurality of interleaved clock signals from each of the plurality of clock signals.

In a twenty-seventh aspect, a time-to-digital converter according to a twenty-fifth aspect, further comprising generating a fine resolution count value from stochastic values of a plurality of stochastic logic elements connected to receive intermediate values of the clock signal.

While the foregoing has been described in conjunction with exemplary aspects, it is understood that the term “exemplary” is merely meant as an example, rather than the best or optimal. Accordingly, the disclosure is intended to cover alternatives, modifications and equivalents, which may be included within the scope of the disclosure.

Although specific aspects have been illustrated and described herein, it will be appreciated by those of ordinary skill in the art that a variety of alternate and/or equivalent implementations may be substituted for the specific aspects shown and described without departing from the scope of the present application. This application is intended to cover any adaptations or variations of the specific aspects discussed herein.

1. A time-to-digital converter, comprising:
an inverter ring configured to generate a clock signal at a clock signal output upon receiving a start signal at a first input;
a flip flop chain including an second input to receive a stop signal and having a stop signal output; and
a time interleaved counter array connected to receive the clock signal from the inverter ring and to receive the stop signal from the flip flop chain, the time interleaved counter array including:
a plurality of counters connected to receive a plurality of interleaved clock signals from the inverter ring and generate partial count signals as counts of the interleaved clock signal received by the corresponding counter; and
a decoder connected to receive the partial count signals and configured to combine the partial count signals into a total count value.

2. A time-to-digital converter as claimed in claim 1, wherein the inverter ring includes a feedback loop connecting the clock signal output to an input of the inverter ring, the inverter ring being a short inverter ring that is operable to generate a clock pulse having a clock period less than a settling time of at least one of the plurality of counters.

3. A time-to-digital converter as claimed in claim 1, wherein the inverter ring includes a plurality of inverters connected in series.

4. A time-to-digital converter, comprising:
an inverter ring including a plurality of inverters connected in series, the inverter ring having a logic gate with a first input to receive a start signal, the logic gate having an output connected to a first inverter in the inverter ring, the inverter ring having a clock signal output, a feedback loop connected from the clock signal output of the inverter ring to a second input of the logic gate, the inverter ring being operable to generate a clock signal at the clock signal output upon receiving the start signal at the first input of the logic gate;
a flip flop chain including a plurality of flip flops connected in series, the flip flop chain including a second input to receive a stop signal, the flip flop chain including flip flops connected to receive outputs of corresponding inverters in the inverter ring, the flip flop chain having a stop signal output, the flip flop chain being operable to output a stop signal; and
a time interleaved counter array connected to receive the clock signal from the inverter ring and to receive the stop signal from the flip flop chain, the time interleaved counter array including:
a plurality of counters connected to receive a plurality of interleaved clock signals from the inverter ring, each of the plurality of counters being operable to generate a partial count signal as a count of the interleaved clock signal received by the corresponding counter; and a decoder connected to receive the partial count signals, the decoder being operable to combine the partial count signals into a total count value, the total count value corresponding to a digital value of a time between the start signal and the stop signal.

5. A time-to-digital converter as claimed in claim 4, wherein the time interleaved counter array includes:
an interleaved clock generator connected to receive the clock signal from the inverter ring and being operable to distribute the clock signal to a plurality of clock outputs as interleaved clock signals; and
wherein the plurality of counters are connected to respective ones of the plurality of clock outputs to each receive a corresponding interleaved clock signal.

6. A time-to-digital converter as claimed in claim 5, wherein the interleaved clock generator distributes the clock signal on a first number of clock outputs, the interleaved clock generator including a divide by first number element connected to receive the clock signal from the inverter ring.

7. A time-to-digital converter as claimed in claim 5, wherein the interleaved clock generator is operable to output a first clock pulse on a first clock output of the plurality of clock outputs and configured to output a second clock pulse on a second clock output of the plurality of clock outputs.

8. A time-to-digital converter as claimed in claim 4, wherein the inverter ring includes a plurality of outputs at which are generated time interleaved clock signals; and
wherein the plurality of counters are connected to respective ones of the plurality of outputs of the inverter ring.

9. A time-to-digital converter as claimed in claim 8, wherein the plurality of outputs of the inverter ring are connected from outputs of a plurality of the inverters in the inverter ring.

10. A time-to-digital converter as claimed in claim 9, wherein the plurality of counters connected to the plurality of outputs of the inverter ring include a plurality of interleaved counters.

11. (canceled)

12. A time-to-digital converter as claimed in claim 4, wherein the flip flop chain includes a chain of stochastic flip flops connected in series, each of the stochastic flip flops including a plurality of flip flops, each stochastic flip flop being operable to generate an output corresponding to an output value of a majority of the flip flops of the stochastic flip flop.

13. A time-to-digital converter as claimed in claim 4, wherein each flip flop in the flip flop chain includes a first input connected to an input of the corresponding inverter in the inverter ring, each flip flop in the flip flop chain including a second input connected to an output of the corresponding inverter in the inverter ring.

14. (canceled)

15. (canceled)

16. A time-to-digital converter as claimed in claim 4, wherein the inverter ring generates a series of clock pulses having a time between subsequent clock pulses less than a relaxation time of the counters, and
wherein the interleaved clock signals have a time between subsequent clock pulses greater than a relaxation time of the counters.

17. A method for determining a time between a start signal and a stop signal, comprising:
generating a clock signal upon receiving the start signal;
dividing the clock signal into a plurality of interleaved clock signals;
counting pulses of each of the interleaved clock signals to accumulate a plurality of partial count values;
combining the plurality of partial count values with one another to obtain a total count value upon receiving the stop signal, the total count value corresponding to a digital indication of a time between the start signal and the stop signal.

18. A method as claimed in claim 17, wherein the generating the clock signal includes generating the clock signal using a short inverter ring.

19. A method as claimed in claim 17, wherein the clock signal generated in the generating step has a time between subsequent clock pulses less than a relaxation time of the counters; and
wherein the interleaved clock signal obtained in the dividing step have a time between subsequent clock pulses greater than a relaxation time of the counters.

20. A method as claimed in claim 17, wherein the total count value is a coarse resolution count value;
wherein the generating the clock signal includes communicating the start signal through a series of logic elements connected in a ring; and further comprising: receiving the outputs of the logic elements in the ring by a series of stochastic logic elements; and
obtaining a fine resolution count value at outputs of the stochastic logic elements.

21. A method as claimed in claim 17, wherein the series of logic elements connected in a ring are inverters connected in an inverter ring.

22. A method as claimed in claim 17, wherein the receiving the outputs of the logic elements by the stochastic logic elements includes receiving an output of a logic element in the series at an inverting input of a stochastic logic element and receiving the same output of the logic element in the series at a non-inverting input of a next subsequent stochastic logic element in the series.

23. A method as claimed in claim 17, wherein the generating the clock signal includes generating a plurality of clock signals; and
wherein the dividing the clock signal includes dividing each of the plurality of clock signals into interleaved clock signals.

24-27. (canceled)
